(19) United States
(12) Patent Application Publication
(10) Pub. No.: US 2013/0143402 A1
(43) Pub. Date: Jun. 6, 2013

(54) Method of forming Cu thin film

(71) Applicant: Nanmat Technology Co., Ltd., Kaohsiung (TW)

(72) Inventors: Cheng-Jye CHU, Kaohsiung (TW); Chih-Hung CHEN, Kaohsiung (TW)

(73) Assignee: NANMAT TECHNOLOGY CO., LTD., Kaohsiung (TW)

(21) Appl. No.: 13/768,992

(22) Filed: Feb. 15, 2013

Related U.S. Application Data
(63) Continuation-in-part of application No. 12/860,035, filed on Aug. 20, 2010.

(51) Int. Cl. H01L 21/02

(52) U.S. Cl. CPC H01L 21/02697
USPC 438/658

(57) ABSTRACT

The disclosure provides a method for forming a dense Cu thin film by atomic layer deposition, comprising the following steps of: (A) providing an additive gas; (B) choosing a copper-containing metal-organic complex as a precursor; (C) using a carrier gas to introduce the additive gas into the precursor cell mixing with the precursor; (D) pre-depositing the precursor on the surface of the substrate with a TaNₓ thin film at a first temperature; (E) removing the excess copper-containing metal-organic complex and the excess additive gas; (F) introducing a reducing gas into the reactive system and annealing at a second temperature to reduce the Cu₂O thin film to form a Cu thin film on the substrate and (G) removing the excess reducing gas from the reactive system.

### CROSS REFERENCE TO RELATED APPLICATIONS

This application is a Continuation-in-Part of co-pending application Ser. No. 12/860,035, filed on Aug. 20, 2010, and for which priority is claimed under 35 §120, the entire contents of which are hereby incorporated by reference.

### BACKGROUND

1. Technical Field

The disclosure provides a Cu based thin film manufacturing process, and more particularly to a method for forming a dense Cu thin film by atomic layer deposition. The method includes the first step of pre-depositing Cu₂O without including CuO, and then the second step of reducing Cu₂O to form a dense Cu thin film.

2. Related Art

Metallization is a process of connecting the transistors on silicon wafer by metal line to form an integrated circuit. When the process technology develops from very-large scale integration (VLSI) to ultra-large scale integration (ULSI), the integrity and speed of device will increase over 0.25 μm, which current density will improve substantially (10⁵ A/cm²) causing electromigration effects. As metal atoms move along the grain boundary resulting in the sectional area of metal line decreasing, the resistance of metal interconnecting line will increase causing resistance capacitance (RC) time delay and decrease of device reliability.

Aluminum is a widely used conducting material in integrated circuits. But silicon and aluminum have a specified solid solubility, which the contacts between aluminum and silicon will come out spiking in the multi-level interconnect system and then the leakage currents of the contacts increase. To solve this problem, TiN/Ti alloy or TiW are generally deposited as a diffusion barrier, But when integrity is below 0.25 μm, all the resistivity and the electromigration of Al and the barrier ability of TiN are not right to the request. Therefore, a metallization process, which has the characteristics of low resistivity, high electromigration, deep sub-micron size (<0.25 μm), low metal diffusion coefficient, low ohmic contact, thermally stable, and diffusion barrier of high adherence, is an urgent need of industry.

Cu and TaN have received increased attention as the materials of metal line and diffusion barrier because of high adherence between TaN and Cu, higher melting point, and thermally stable, which is currently deposited by sputtering of physical vapor deposition. In addition, the resistivity of Cu is lower than of Al (rCu_{(20° C.)}=1.645 μW-cm; rAl_{(20° C.)}=2.825 μW-cm), so that electromigration is better under high current density (10⁹ A/cm²). Therefore, Cu and TaN are fitted for very-large scale integration process. In order to achieve the requests of good step coverage, via-fill capability, and deep sub-micron size of high aspect ratio grooves, depositing Cu thin film by metalized organic chemical vapor disposition (MOCVD) is a good choice.

The current chemical vapor disposition is that the halides of Cu react with oxygen, or different metal-organic precursors are utilized to grow the Cu film needed in semiconductor. However, the hybrid membrane of CuO and Cu₂O is obtained instead of the Cu thin film, which makes the oxygen contents in semiconductor hard to control and affects the quality of Cu thin film. Hence, a low resistivity, smoother, and denser Cu film can not be obtained from this method.

U.S. Pat. No. 7,166,732, U.S. Pat. No. 7,241,912, and U.S. Pat. No. 7,371,880, issued to Xu et al, disclose novel copper(l) amidinates as copper-containing metal-organic complexs and their synthesis. The deposition of copper thin films with useful electrical properties and good adhesion to the barrier layer, are achieved by the process and the precursors. However, they didn't mention that an even surface of Cu-thin film can be formed by these copper(I) amidinate precursor.

U.S. Pat. No. 6,511,609, issued to Jan at al, discloses a novel method of Cu seed layer deposition for ULSI metallization. The prepared substrate was sunk in a replacing solution which contains CuSO₄.5H₂O and other reactant containing Cu ions. The dense copper membrane with a resistance of about 1.8 μΩ·cm was obtained. However, it didn't mention the adhesion to the barrier layer.

U.S. Pat. No. 6,194,316, issued to Oda et al, discloses a method for forming a Cu-thin film, which includes the steps of coating a dispersion containing Cu-containing ultrafine particles individually dispersed therein on a semiconductor substrate; and then firing the coated semiconductor substrate in an atmosphere. The specific resistance of the film was found to be 2.0 μΩ·cm. However, to form an even surface of Cu-thin film, a chemical mechanical polishing (CMP) treatment is required to remove the excess Cu present on the surface of the substrate, which Cu film is likely to be peeled off.

There are some other researches described to change different operating conditions, such as various adsorption amounts, reacting temperature, annealing temperature, plasma, and ligands, but a Cu film with the characteristics of low resistivity, smooth, and dense is still not obtained.

### SUMMARY OF THE DISCLOSURE

The disclosure has been developed to solve the previously described problems of fabricating Cu thin film associated with conventional techniques, and it is accordingly an objective of the disclosure to provide a valid and practicable method of forming a dense Cu thin film with excellent qualities.

The objective of the disclosure is to provide a method of forming a dense Cu thin film, which mainly uses two step growth processes by atomic layer deposition (ALD). The method having two important steps includes the first step of pre-depositing Cu₂O and the second step of reducing Cu₂O to form. Cu thin film by annealing.

In order to achieve the objective, the disclosure provides a method of forming a dense Cu thin film by atomic layer deposition, which mainly includes the steps of:
(A) providing an additive gas in an additive cell, the additive gas selected from the group consisting of hydrogen peroxide vapor, water vapor, and alcohol vapor;
(B) choosing a copper-containing metal-organic complex as a precursor disposed in a precursor cell, the copper-containing metal-organic complex being a copper (II)(β-diketonate)₂ complex;
(C) using a carrier gas to introduce the additive gas into the precursor cell mixing with the precursor and then into a reactive system comprising a substrate having two surfaces, the carrier gas comprising an inert gas not participating in the reaction, wherein one surface of the substrate comprises a TaNₓ thin film prepared using atomic layer deposition, the x ranging from 0.01 to 0.5, and the thickness of the TaNₓ thin film ranging from 1 nm to 5 nm;
(D) pre-depositing the precursor on the surface of the substrate with a TaNₓ thin film at a first temperature in a range of from 90° C. to 250° C. to form a Cu₂O thin film without including CuO, wherein only part of the copper-containing metal-organic complex and part of the additive gas are used for forming the Cu₂O thin film, part of copper-containing metal-organic complex not used for forming the Cu₂O thin film is an excess copper-containing metal-organic complex and part of the additive gas not used for forming the Cu₂O thin film is an excess additive gas;
(E) removing the excess copper-containing metal-organic complex and the excess additive gas from the reactive system;
(F) introducing a reducing gas into the reactive system and annealing at a second temperature in a range of from 50° C. to 250° C. to reduce the Cu₂O thin film without including CuO to form a dense Cu thin film on the substrate, wherein only part of the reducing gas is used for forming theslense Cu thin film and part of the reducing gas not used for forming the dense Cu thin film is an excess reducing gas;
(G) removing the excess reducing gas from the reactive system; and
(H) repeating step (A) to step (G) for a plurality of times to obtain a desired thickness of the dense Cu thin film.

According to the disclosure, a proper Cu containing metal-organic precursor is chosen to deposit a Cu₂O thin film without including CuO on a substrate and then to reduce the Cu₂O to form a smooth and dense Cu thin film by annealing, which will improve the purity and the quality of Cu thin film and CuO thin film.

The invention itself, though conceptually explained above, can be best understood by referencing to the following description, taken in conjunction with the accompanying drawings.

### BRIEF DESCRIPTION OF THE DRAWINGS

FIG. 1: diagram of the deposition system of the disclosure;

FIG. 2: XRD pattern of deposited Cu₂O film;

FIG. 3: Cu Auger patterns of (a) pre-depositing Cu₂O for 20 minutes and (b) reducing by ethanol for 3 minutes;

FIG. 4: O1s XPS patterns of (a) pre-depositing Cu₂O for 30 minutes and (b) reducing by ethanol for 3 minutes;

FIG. 5: 30K-fold SEM image of Cu deposited by two-step growth; and

FIG. 6: 300K-fold SEM cross-section image of Cu deposited by atomic layer deposition.

### DETAILED DESCRIPTION OF THE PREFERRED EMBODIMENTS

According to the disclosure, the important feature of the present method is that first forming a monovalent copper (Cu₂O) thin film without including CuO from a metal-organic complex containing divalent copper and then reducing the monovalent copper thin film to form dense copper film by atomic layer deposition.

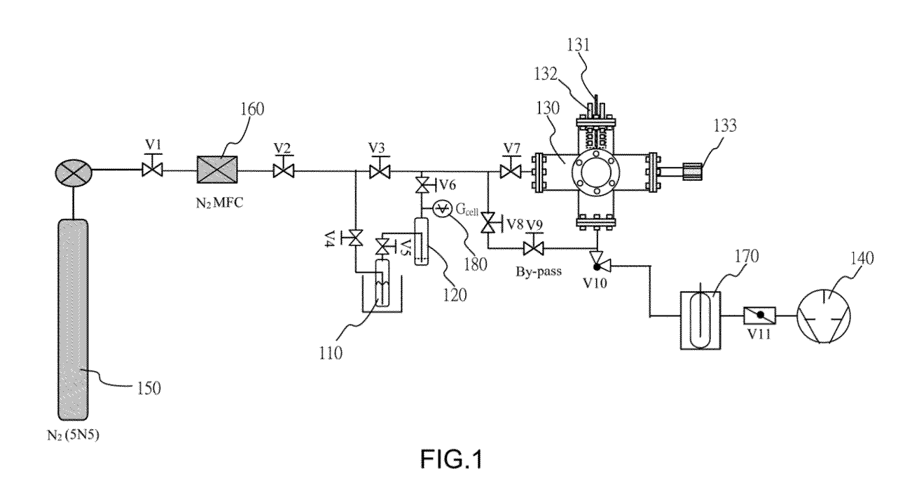

Please refer FIG. 1, it shows typical diagram of the deposition system of the disclosure. In FIGS. 1, V1 and V2 are ball valves (WHITEY SS-42S4); V3 is bellows valve (WHITEY SS-4H); V4, V6, V8, and V9 are plug valves (NUPRO SS-4P4T); V7 is a toggle valve (WHITEY SS-1GS4); V10 is angle valve (BALZERS EVA 025S); V11 is butterfly valve.

The disclosure provides a novel method of forming a dense Cu thin film by atomic layer deposition (ALD), which mainly includes the steps of:
(A) providing an additive gas in an additive cell 110, the additive gas selected from the group consisting of hydrogen peroxide vapor, water vapor, and alcohol vapor. In this step, the additive gas is provided through V5 into precursor cell 120.
(B) choosing a copper-containing metal-organic complex as a precursor disposed in a precursor cell 120, the copper-containing metal-organic complex being a copper (II)(β-diketonate)₂ complex.
(C) using a carrier gas to introduce the additive gas into the precursor cell 120 mixing with the precursor and then go through controlling V6 and V7 into a reactive system 130 comprising a substrate having two surfaces, the carrier gas comprising an inert gas not participating in the reaction, wherein one surface of the substrate comprises a TaNₓ thin film prepared using atomic layer deposition, the x ranging from 0.01 to 0.5, and the thickness of the TaNₓ thin film ranging from 1 nm to 5 nm. In this step, the carrier gas is provided through gas cylinder 150, V1 mass flow controller (MFC) 160, V2, V4, and then the additive cell 110 to carry the additive gas.
(D) pre-depositing the precursor on the surface of the substrate with a TaNₓ thin film at a first temperature in a range of from 90° C. to 254° C. to form a Cu₂O thin film without including CuO, wherein only part of the copper-containing metal-organic complex and part of the additive gas are used for forming the Cu₂O thin film, part of copper-containing metal-organic complex not used for forming the Cu₂O thin film is an excess copper-containing metal-organic complex and part of the additive gas not used for forming the Cu₂O thin film is an excess additive gas.
(E) removing the excess copper-containing metal-organic complex and the excess additive gas from the reactive system 130. The step is performed by mechanical pump 140, V11, cold trap 170 and V10 in FIG. 1.
(F) introducing a reducing gas into the reactive system 130 and annealing at a second temperature in a range of from 50° C. to 250° C. to reduce the Cu₂O thin film without including CuO to form a dense Cu thin film on the substrate, wherein only part of the reducing gas is used for forming the dense Cu thin film and part of the reducing gas not used for forming the dense Cu thin film is an excess reducing gas.
(G) removing the excess reducing gas from the reactive system 130. The step is performed by mechanical pump 140, V11, cold trap 170 and V10 in FIG. 1.
(H) repeating step (A) to step (G) for a plurality of times to obtain a desired thickness of the dense Cu thin film.

The formation of Cu₂O layer without including CuO is carried out by atomic layer deposition using copper-containing metal-organic precursor and the additive gas at a low temperature, preferably below about 250° C. In a preferred embodiment, the step (D) and the step (F) are carried out at a work pressure of the reactive system 130 in the range of 50 mTorr to 500 mTorr.

Taking the precursor Cu(II)(hfac)₂ as an example, the reaction equation is as follows:

2 Cu(II)(hfac)_{2(g)}+H₂O→Cu₂O_{(g)}+2H(hfac)_{(g)}+2hfac₍ₛ₎

hfac₍ₛ₎→byproducts_{(g)}

C₂H₅OH→CH₃CHO+2H

Cu₂O+2H→2Cu+H₂O

In the above reactions, the few catalyst Cu comes from the pre-deposition of the Cu(II)(hfac)₂, where the few catalyst Cu can oxidize the ethanol into acetaldehyde and dissociate hydrogen atoms, which not only obtains the dense Cu thin film, but also lowers the reaction temperature. Moreover, by using the alcohol/water mixed vapor to pre-deposit the Cu₂O thin film, it can stabilize the vapor pressure of the copper-containing metal-organic precursor, which results denser Cu₂O thin film with smaller grain size.

In the prior art, hydrogen gas is used as the reducing gas to reduce the Cu₂O thin film to Cu thin film. However, high temperature and long reaction time are necessary to decompose hydrogen gas into hydrogen atoms. Moreover, without forming the Cu₂O thin film by mixing the precursor with the additive gas first, the mixed phase of Cu, CuO, and Cu₂O will co-exist in the formed thin films, which may not form the dense Cu thin film after reducing. In the other embodiment, the additive gas is alcohol/hydrogen peroxide mixed vapor.

Of advantage, the atomic layer deposition can be performed at a comparatively lower temperature, which is compatible with the industry's trend toward lower temperatures. Atomic layer deposition has many advantages of high precursor utilization efficiency, producing conformal thin film layers, easily controlling film thickness on an atomic scale, and forming “nano-engineer” complex thin films. In an ALD process deposition cycle, each reactant gas is introduced independently into a reaction chamber, so that no gas phase intermixing occurs. A monolayer of a first reactant is physi- or chemisorbed onto the substrate surface. Excess first reactant is evacuated from the reaction chamber preferably with the aid of an inert purge gas. A second reactant is then introduced to the reaction chamber and reacted with the first reactant to form a monolayer of the desired thin film via a self-limiting surface reaction. The self-limiting reaction stops once the initially adsorbed first reactant fully reacts with the second reactant. Excess second reactant is evacuated, preferably with the aid of an inert purge gas. A desired film thickness is obtained by repeating the deposition cycle as necessary. The film thickness can be controlled to atomic layer accuracy by simply counting the number of the deposition cycles. Therefore, the step (A) to step (G) are repeated for several times to obtain a desired thickness of the dense Cu thin film.

It is deserved to be is worth mentioned mentioning that there are two factors determining the resistivity of metal thin film. One is the contents of impurities; the other is the density of thin film. Wherein the larger grain size is and the smaller grain boundary size is, the higher density is, relatively. The pre-deposition and annealing temperature of the disclosure can satisfy the said factors efficiently. From the said in this distribution, the method fabricating the Cu thin film and the CuO thin film of the disclosure uses two-step growth process to reduce the pre-deposited Cu₂O to Cu thin film on the substrate, or to oxidize the Cu₂O to CuO thin film, so that a smooth and dense film with low resistivity, high reflection, and low roughness is formed. On the other hand, the precursor is only carried within the pre-deposition process. In comparison with to the traditional method of forming Cu film, the precursor consumptions of the precursor will is reduced significantly likewise reducing costs and pollution. In addition, because the pre-deposition temperature is lower (<250° C.), precursor pyrolysis will not break the bonding within the ligands, thus keeping the ligands intact and making them reusable. This condition is beneficial to environmental protection, and further solves the environmental problems resulting from the traditional method of forming Cu thin film.

The Cu of the copper-containing metal-organic complex chosen in the disclosure is either copper(I) or copper(II). The complex containing copper(I) is a (β-diketonate)copper(I)L complex, wherein β-diketonate is selected from the group consisting of hexafluoroacetylacetone (hfac), acetylacetone (acac), 2,2,6,6-tetramethyl-3,5-heptanedione (thd), ethyl 3-oxobutanoate (etac), tert-butyl 3-oxobutanoate (btac), and etc . . . ; L is an electron donating ligand, which is selected from the group consisting of alkyl, alkyl phosphite, alkyl phosphine, alkyne, and silane, such as 1,5-cyclo-octadiene (1,5-COD), vinyltrimethyl-silane (VTMS), vinyltrimethoxy silane (VTMOS), 2-butyne, 2-pentyne, trialkylphosphite, trialkylphosphine and so on. In the preferable embodiments, the complex containing copper(II) is a copper(II)(β-diketonate) complex, which is selected from the group consisting of Cu(II)(hfac)₂, Cu(II)(acac)₂, Cu(II)(thd)₂, Cu(II)(btac)₂, Cu(II)(etac)₂ and so on.

The carrier gas is an inert gas such as nitrogen gas, helium gas, and silane not participating in the reaction, and is chosen to carry the precursor into the reacting system. Furthermore, additive gas such as hydrogen peroxide vapor, water vapor, and alcohol vapor can contribute to stabilize the vapor pressure of the precursor. In a preferred embodiment, the additive gas is alcohol/water mixed vapor, and the molar ratio of the alcohol vapor to the water vapor in which ranges from 0.5 to 5. In another preferred embodiment, the additive gas is alcohol/hydrogen peroxide mixed vapor, and the molar ratio of the alcohol vapor to the water vapor in c alcohol/hydrogen peroxide mixed vapor ranges from 0.5 to 5.

The proper substrate, which is able to contact with Cu interconnecting lines in an IC process, is selected from the group consisting of materials of diffusion barrier, such as titanium oxide, tantalum oxide, and tungsten oxide; materials of insulator layer, such as silicon, silicon oxide, silicon nitride, and titanium oxide; metal materials, such as tungsten and aluminum; dielectric materials, such as silicon, silicon carbon, and tantalum oxide; superconductor and materials contacting with superconductor.

In a preferred embodiment, the substrate used in the disclosure comprises a TaNₓ thin film prepared using atomic layer deposition on one surface of the substrate, the x ranging from 0.01 to 0.5, and the thickness of the TaNₓ thin film ranging from 1 nm to 5 nm. It is noted that by using the substrate with a TaNₓ thin film on the one surface of the substrate, the dense Cu thin film by atomic layer deposition (ALD) can be achieved easily. In an embodiment, the TaNx thin film prepared using atomic layer deposition is provided as the diffusion barrier on the silicon substrate or TaN substrate. The high TaiN ratio of the ALD-TaNₓ layer can reduce the resistivity of the ALD-TaNₓ layer and improve the adhesion between the Cu layer and the diffusion barrier. The resistivity of the TaNₓ thin film ranges from 40 μΩ-cm to 150 μΩ-cm, and the thickness of the TaNₓ thin film ranges from 1 nm to 5 nm. The lower ratio x allows the TaNx thin film having higher resistivity. The preferred ratio x is 0.1. By using the method and the conditions mentioned above, the Cu₂O thin film without including CuO has the grain size of 1 nm to 30 nm,

The pre-depositing step (D) is at a first temperature in a range of from 25° C. to 600° C., the precursor will form a pre-deposited Cu₂O thin film on a proper substrate. Preferably, the first temperature in the pre-depositing step is in a range of from 90° C. to 250° C. in which the temperature control is through the cooperation with heater 132 and thermocouple 131. And more preferably, the first temperature in the pre-depositing step is in a range of from 100° C. to 200° C., to reduce the fabrication variety. The precursor is introduced at a flow rate in the range of 5 to 50 sccm. To form a monolayer on the surface of substrate, the precursor is introduced in pulse at a pulse time of 0.05 to 10 seconds and is preferably in the range of 0.1 to 2 seconds. Only part of the copper-containing metal-organic complex and the additive gas are used for forming the Cu₂O thin film without including CuO, part of copper-containing metal-organic complex not used for forming the Cu₂O thin film is an excess copper-containing metal-organic complex and part additive gas not used for forming the Cu₂O thin film is an excess additive gas. At the end of the precursor pulse, the copper-containing metal-organic complex vapor flow into the reactive system 130 is terminated, and the excess copper-containing metal-organic complex and excess additive gas are removed from the reactive system 130.

Next, in the step (E), stop the supply of the precursor, and retain the conducting gas or increase the other conducting gases and additive gases. Meanwhile, proceed with annealing at a second temperature in a range of from 50° C. to 250° C. or offer the other energy to reduce the Cu₂O without including CuO to form Cu thin film. And more preferably, the second temperature in the step (E) is in a range of from 150° C. to 200° C., to reduce the fabrication variety. Light, heat, plasma, and high energy particle can offer the energy for annealing with the reducing gas. In an embodiment, the reducing gas is selected from the group consisting of hydrogen peroxide vapor, water vapor, and alcohol vapor. If alcohol vapor is used as a reducing gas, Cu₂O without including CuO will be reduced simply to Cu forming Cu thin film. If carbon monoxide or oxygen is used as annealing gas, Cu₂O will be oxidized to CuO, forming CuO thin film. The reducing gas is introduced at a flow rate in the range of 5 to 100 sccm.

In the step (F), the reducing gas is purged from the reactive system 130 with an inert gas for an appropriate period of time. The whole sequence of steps then repeated as many times as desired to form a dense copper layer with a desire thickness. After reducing the Cu₂O thin film without including CuO, the dense Cu thin film with the grain size of 1 nm to 30 nm can be obtained, wherein the resistivity of the obtained Cu thin film is below 2.5 μΩ-cm.

In step (G), the excess reducing gas is removed from the reactive system 130. It is noted that in the step (H), the step (A) to the step (G) are repeated for a plurality of times to obtain a desired thickness of the dense Cu thin film. For example, the step (A) to the step (G) are repeated for 100 times to obtain a dense Cu thin film with 6 nm thickness. Thus, the a plurality of times for repeating the step (A) to the step (G) are ranging from 20 times to 500 times.

The method for forming a Cu thin film according to the disclosure will hereinafter be described in more detail with reference to the following working Examples, but the disclosure is not restricted to these specific Examples at all.

### Example 1

Cu (btac)₂ is used as the precursor, and copper then be deposited on the wafer using a chemical vapor deposition system. A TaN substrate is pre-heated to a temperature of 250° C. in a vacuum of not higher than 10⁻² torr for 2 minutes to remove the organic solvent and fired in a vaccum atmosphere in the presence of hydrogen gas (hydrogen particle pressure: 10⁻⁹ torr) for 60 minutes while raising the temperature up to 300° C. A Cu₂O thin film is formed on a TaN substrate. Moreover, the substrate is fired in a reducing gas of alcohol vapor for 30 minutes while raising the temperature up to 400° C. Thus, the Cu₂O thin film will be reduced to form Cu film.

### Example 2

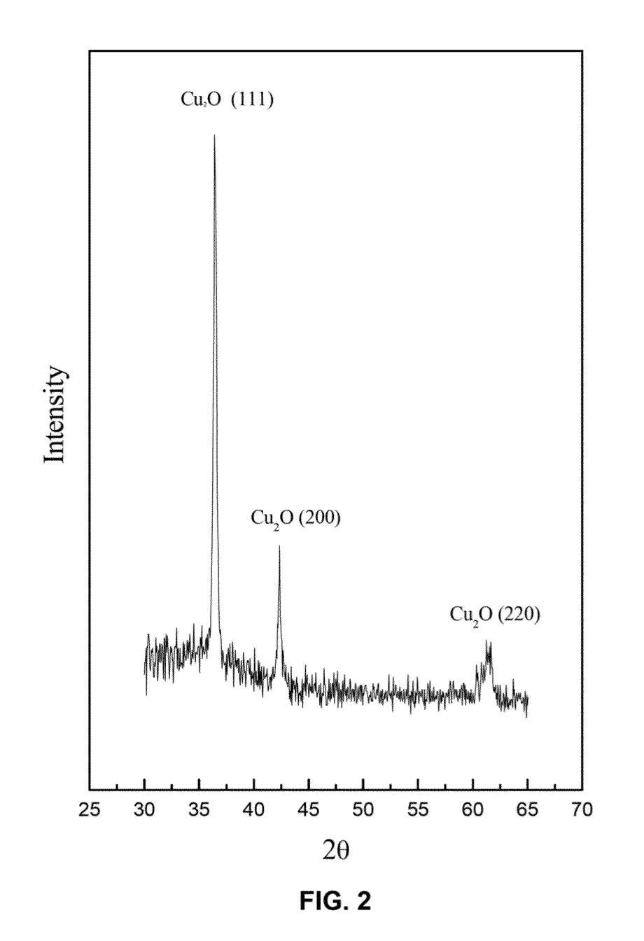

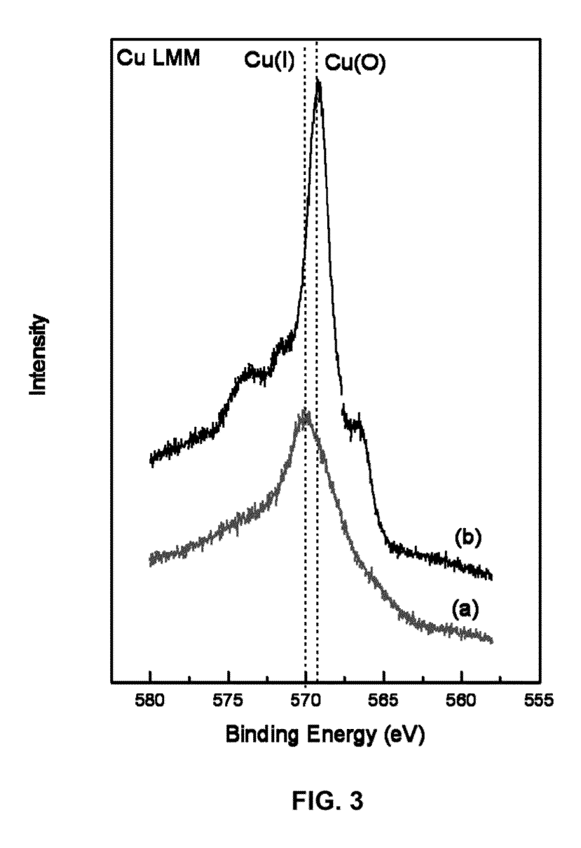

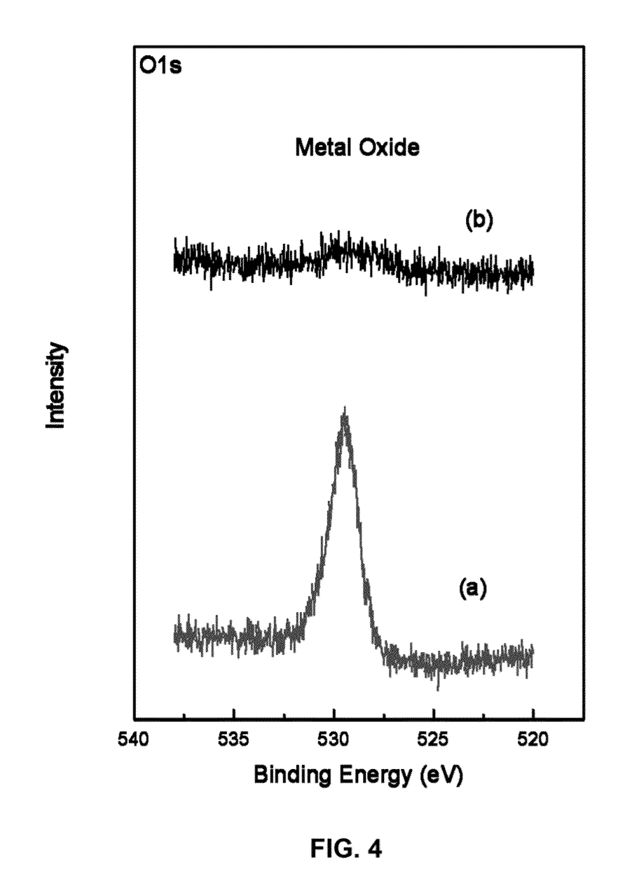

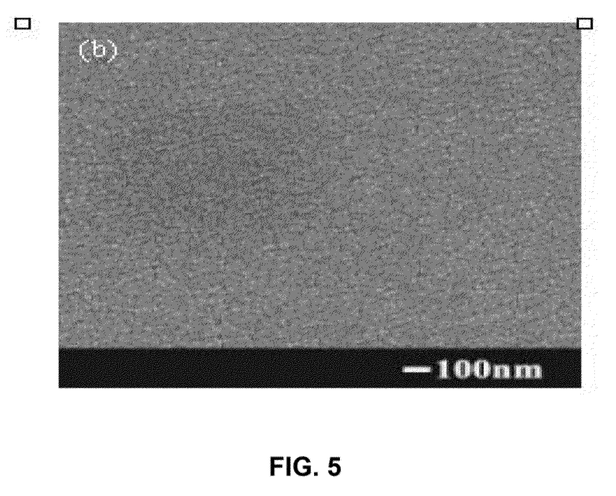

Cu(hfac)₂ is used as the precursor of chemical vapor deposition to proceed two-step growth. In other words, water vapor is added first to pre-deposit Cu₂O thin film on a TaN substrate, and annealing and reducing is then carried out to form Cu m by alcohol vapor, The experimental conditions may include Cu₂O is pre-deposited at a pressure of 0.1 torr at 275° C.; precursor evaporator is at 65° C.; nitrogen gas flows at 7.5 sccm; and add water vapor as carrier gas. The results are shown in FIG. 2. Note in the XRD diagram of FIG. 2, that the peak positions at 2θ=36.4°, 42.2°, and 61.3° correspond to (111), (200), and (220) of Cu₂O respectively and there is no characteristic peak of CuO present in the XRD diagram. The results, conditions of which include nitrogen gas flows at 7.5 sccm to carry alcohol vapor and reduce at a pressure of 0.4 torr at 275° C. for 3 minutes, are shown in FIG. 3, FIG. 4, and FIG. 5.

FIG. 3 shows the Cu LMM Auger patterns. We should utilize Cu LMM Auger to observe the presences of Cu(0) and Cu(I). From the Cu LMM Auger patterns, it is found that the positions of Cu(0) and Cu(I) is present at 568.2 and 570.1 eV respectively. But Cu(0) and Cu(I) are still not distinguished from the Cu LMM Auger patterns, because there are some overlaps within the LMM patterns of Cu(0) and Cu(I). Therefore, we have to analyze the quantity of the oxygen contained in thin film. From FIG. 4, we can know that the peak position of oxygen is not very obvious after annealing by alcohol vapor for 3 minutes, which means there is almost no oxygen existing. Hence, it is proved that Cu₂O is reduced to Cu thin film indeed instead of CuO thin film or Cu₂O thin film.

In respect of structure, FIG. 5 shows the SEM image of Cu deposited by two-step growth. It can be found that the surface morphology of Cu thin film deposited by two-step growth is extremely dense and without any void. It is because that the Cu thin film grown directly will crack to from Cu under higher temperature. If there are some Cu-cores in the defects of TaN substrate with high resistivity, the following precursor pyrolysis deposition will occur on Cu-cores to form Cu, which Cu atom can be offered to absorb the medium produced from precursor pyrolysis, resulting larger and denser grains. In the meantime, Hfac produced from pyrolysis will react with Cu to form Cu(hfac) and then desorb, which is a etching reaction and also a reason that film is not dense. On the contrary, Cu₂O is produced first within two-step pre-deposition process, which means the deposition without selectivity will be occurred after precursor pyrolysis. Besides, the surface free energy of CuO is lower, which is easier to wet the surface of substrate, so that CuO will plate on the surface uniformly. In addition, there is no etching reaction of Hfac when annealing, and the crystalline of Cu begin to nucleate and regrow from the interface, so that a smooth and dense film can be deposited.

### Example 3

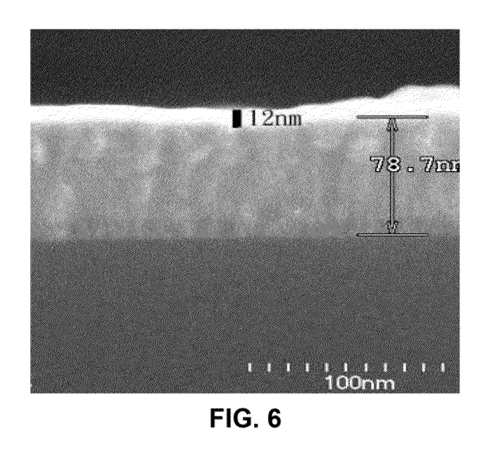

Cu(hfac)₂ is used as the precursor of atomic layer deposition to proceed two-step growth. Alcohol/hydrogen peroxide (1:1) mixed vapor as the additive gas is introduced to the precursor cell 120 with N₂ gas as the carrier gas and mixed with Cu(hfac)₂. And then, the mixed gas is introduced into the chamber containing the silicon substrate with a 3 nm TaN_{0.1} thin film prepared using atomic layer deposition deposited on the surface of the silicon substrate. The precursor is introduced at a flow rate of 10 sccm and the pulse time of 2 seconds. The first temperature is 120° C., and the pressure of the chamber of the reactive system 130 is 200 mTorr, in which the pressure control is through the capacitance diaphragm gauge 133. Next, stop introducing the precursor, and pump down for 10 seconds, A smooth and Cu₂O thin film without including CuO is pre-deposited on the TaN_{0.1} deposited substrate, Next, alcohol vapor as the reducing gas is introduced into the chamber and then alcohol vapor reduces the Cu₂O thin film without including CuO to form a dense Cu thin film on the TaN_{0.1} deposited substrate. The reducing gas is introduced at the flow rate of 10 sccm and the pulse time of 5 seconds. The second temperature is 150° C., and the pressure of the chamber of the reactive system 130 is 60 mTorr. Finally, stop introducing the alcohol vapor, and pump down for 10 seconds. It is noted that the above steps are repeated for 200 cycles, and a smooth and dense Cu thin film with thickness of 12 nm is obtained, as shown in FIG. 6. The resistivity of the obtained Cu thin film is about 1.9 μΩ-cm. The impurities in the Cu thin film are less than 0.1 atom %.

### Example 4

The experimental conditions are the same as example 3, in which there is a TaN_{0.1} thin film with thickness of 5 nm on the TaN substrate. That is, the Cu(hfac)₂ precursor is introduced to pre-deposit smooth and Cu₂O thin film on the TaN_{0.1}TaN substrate, and then reduce the Cu₂O thin film to form a smooth and dense Cu thin film. The resistivity of the obtained Cu thin film is about 1.83 μΩ-cm. The impurities in the Cu thin film are less than 0.1 atom %.

As has been described above in detail, the forming method of Cu thin film according to the disclosure indeed improves the quality of Cu thin film, lowers the cost of process, provides with environmental protection, and thus permits the formation of a conductive, uniform and fine pattern.

According to the disclosure, the feature of the present method is that first forming a monovalent copper thin film from a metal-organic complex containing divalent copper and then reducing the monovalent copper thin film to form dense copper film by atomic layer deposition.

While the disclosure has been described by the way of example and in terms of the preferred embodiments, it is to be understood that the invention need not to be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A method for forming a dense Cu thin film by atomic layer deposition, comprising the following steps of:
(A) providing an additive gas in an additive cell, the additive gas selected from the group consisting of hydrogen peroxide vapor, water vapor, and alcohol vapor;
(B) choosing a copper-containing metal-organic complex as a precursor disposed in a precursor cell, the copper-containing metal-organic complex being a copper (II)(β-diketonate)₂ complex;
(C) using a carrier gas to introduce the additive gas into the precursor cell mixing with the precursor and then into a reactive system comprising a substrate having two surfaces, the carrier gas comprising an inert gas not participating in the reaction, wherein one surface of the substrate comprises a TaNₓ thin film prepared using atomic layer deposition, the x ranging from 0.01 to 0.5, and the thickness of the TaNₓ thin film ranging from 1 nm to 5 nm;
(D) pre-depositing the precursor on the surface of the substrate with a TaNₓ thin film at a first temperature in a range of from 90° C. to 250° C. to form a Cu₂O thin film without including CuO, wherein only part of the copper-containing metal-organic complex and part of the additive gas are used for forming the Cu₂O thin film, part of copper-containing metal-organic complex not used for forming the Cu₂O thin film is an excess copper-containing metal-organic complex and part of the additive gas not used for forming the Cu₂O thin film is an excess additive gas;
(E) removing the excess copper-containing metal-organic complex and the excess additive gas from the reactive system;
(F) introducing a reducing gas into the reactive system and annealing at a second temperature in a range of from 50° C. to 250° C. to reduce the Cu₂O thin film without including CuO to form a dense Cu thin film on the substrate, wherein only part of the reducing gas is used for forming the dense Cu thin film and part of the reducing gas not used for forming the dense Cu thin film is an excess reducing gas;
(G) removing the excess reducing gas from the reactive system; and
(H) repeating step (A) to step (G) for a plurality of times to obtain a desired thickness of the dense Cu thin film.

2. The method for forming a dense Cu thin film by atomic layer deposition as claimed in claim 1, wherein the copper-containing metal-organic complex is selected from the group consisting of Cu(II)(hfac)₂, Cu(II)(acac)₂, Cu(II)(thd)₂, Cu(II)(btac)₂, and Cu(II)(etac)₂.

3. The method for forming a dense Cu thin film by atomic layer deposition as claimed in claim 1, wherein the additive gas is alcohol/water mixed vapor, and the molar ratio of the alcohol vapor to the water vapor in alcohol/water mixed vapor ranges from 0.5 to 5.

4. The method for forming a dense Cu thin film by atomic layer deposition as claimed in claim 1, wherein the additive gas is alcohol/hydrogen peroxide mixed vapor, and the molar ratio of the alcohol vapor to the water vapor in alcohol/hydrogen peroxide mixed vapor ranges from 0.5 to 5.

5. The method for forming a dense Cu thin film by atomic layer deposition as claimed in claim 1, wherein the reducing gas is selected from the group consisting of hydrogen peroxide vapor, water vapor, and alcohol vapor.

6. The method for forming a dense Cu thin film by atomic layer deposition as claimed in claim 1, wherein a resistivity of the TaNₓ thin film ranges from 40 μΩ-cm to 150 μΩ-cm.

7. The method for forming a dense Cu thin film by atomic layer deposition as claimed in claim 1, wherein the step (D) and the step (F) are carried out at a work pressure of the reactive system in the range of 50 mTorr to 500 mTorr.

8. The method for forming a dense Cu thin film by atomic layer deposition as claimed in claim 1, wherein the precursor is introduced at a flow rate in the range of 5 to 50 sccm and introduced in pulse at a pulse time of 0.05 to 10 seconds.

9. The method for forming a dense Cu thin film by atomic layer deposition as claimed in claim 1, wherein the reducing gas is introduced at a flow rate in the range of 5 to 100 sccm.

10. The method for forming a dense Cu thin film by atomic layer deposition as claimed in claim 1, wherein a grain size of the Cu₂O thin film without including CuO is in the range of 1 nm to 30 nm.
